(19) United States
(12) Patent Application Publication
(10) Pub. No.: US 2010/0203246 A1
(43) Pub. Date: Aug. 12, 2010

(54) DEPOSITION METHOD AND DEPOSITION APPARATUS FOR NITRIDE FILM

(75) Inventors: Kanji Yasui, Niigata (JP); Hiroshi Nishiyama, Niigata (JP); Kazuyuki Tamura, Niigata (JP); Yasunobu Inoue, Niigata (JP)

Correspondence Address: IPUSA, P.L.L.C, 1054 31ST STREET, N.W., Suite 400, Washington, DC, 20007, US

(73) Assignees: National University Corporation Nagaoka University of Technology, Nagaoka-Shi, Niigata (JP); Tokyo Electron Limited, Minato-Ku, Tokyo (JP)

(21) Appl. No.: 12/669,575

(22) PCT Filed: Jul. 18, 2008
(86) PCT No.: PCT/JP2008/063050

§ 371 Date: Feb. 1, 2010

(30) Foreign Application Priority Data
Jul. 20, 2007 (JP) 2007-189475

(51) Int. Cl. C23C 16/44; C23C 16/34; C23C 16/00

(52) U.S. Cl. 427/255.394; 118/715

(57) ABSTRACT

A deposition method of depositing a nitride film, including steps of introducing one or more nitrogen supplying gas selected from hydrazine and nitrogen oxides into a catalyst reaction apparatus; enabling a reactive gas generated by contacting the nitrogen supplying gas with catalyst to be spouted out from the catalyst reaction apparatus; and reacting the reactive gas with a compound gas, thereby depositing a nitride film on a substrate is disclosed.

### TECHNICAL FIELD

The present invention relates to a technology for depositing nitride films which are useful as semiconductor materials, by depositing nitride, such as gallium nitride and aluminum nitride, on a substrate.

### BACKGROUND ART

Nitrides such as gallium nitride (GaN) and aluminum nitride (AlN) are wide energy gap semiconductors characterized by a high melting point, chemical stability, a high breakdown voltage, a high saturated drift velocity, and the like, and are expected as next generation hard electronics materials.

As methods for forming nitride films such as GaN and the like on various substrate surfaces, various methods such as Pulse Laser Deposition (PLD), laser ablation, sputtering, various Chemical Vapor Depositions (CVDs) or the like are proposed (for example, refer to Patent Documents 1 through 3).

Patent Document 1: Japanese Laid-Open Patent Publication No.2004-327905

Patent Document 2: Japanese Laid-Open Patent Publication No.2004-103745

Patent Document 3: Japanese Laid-Open Patent Publication No.Hei8-186329

According to these proposed methods, a target is prepared in advance, and laser, high-velocity microparticles or the like are irradiated on the target surface in order to deposit a thin film of the target microparticles generated from the target surface onto the substrate surface; a metal organic compound or the like is made to contact the substrate surface heated to a high temperature, together with a reactive gas, utilizing the thermal decomposition reaction generated at the substrate surface; or, a mixture gas of the metal organic compound or the like and the reactive gas is discharged and decomposed by forming plasma in order to deposit a film through recombination of radicals. Therefore, these methods require a large amount of energy to deposit the nitride film. In addition, when depositing, for example, a GaN film, ammonia gas greater than a thousand times that of a Ga source needs to be supplied in a conventional Metal Organic Chemical Vapor Deposition (MOCVD) method, because the ammonia gas is persistent. From a viewpoint of resource saving, and because considerable expense is needed to process unreacted toxic ammonia gas, improvement has been desired.

### DISCLOSURE OF THE INVENTION

### Problems to be Solved by the Invention

Therefore, it is an object of the present invention to provide a technique that solves the problem of the conventional technique, and efficiently forms a nitride film on a substrate at a low cost, by utilizing chemical energy generated by catalyst reaction.

### Means of Solving the Problems

As a result of diligent investigations by the inventors of this invention, it has been found that the above problems can be solved by introducing one or more nitrogen supplying gas selected from hydrazine and nitrogen oxides into a catalyst reaction apparatus; enabling a reactive gas generated by contacting the nitrogen supplying gas with a catalyst to be spouted out from the catalyst reaction apparatus; and reacting the reactive gas with a compound gas.

In other words, a first aspect of the present invention provides a deposition method of depositing a nitride film, including introducing one or more nitrogen supplying gas selected from hydrazine and nitrogen oxides into a catalyst reaction apparatus; enabling a reactive gas generated by contacting the nitrogen supplying gas with catalyst to be spouted out from the catalyst reaction apparatus; and reacting the reactive gas with a compound gas, thereby depositing a nitride film on a substrate.

A second aspect of the present invention provides a deposition method as recited in the first aspect, wherein the catalyst reaction apparatus is arranged in a reaction chamber evacuatable to a reduced pressure; wherein the catalyst is in a form of particles; and wherein the compound gas is a metal organic compound gas.

A third aspect of the present invention provides a deposition method as recited in the first aspect, wherein the compound gas is a gas of a metal compound.

A fourth aspect of the present invention provides a deposition method as recited in the third aspect, wherein the metal compound is a metal organic compound.

A fifth aspect of the present invention provides a deposition method as recited in the fourth aspect, wherein the metal organic compound is a metal organic compound of at least one kind of metal selected from gallium, aluminum, and indium.

A sixth aspect of the present invention provides a deposition method as recited in the first aspect, wherein the compound gas is a gallium-containing gas.

A seventh aspect of the present invention provides a deposition method as recited in the first aspect, wherein the compound gas is a gas of a silicon compound.

An eighth aspect of the present invention provides a deposition method as recited in the seventh aspect, wherein the silicon compound is one of an organic silicon compound, a silicon hydride, and a silicon halide.

A ninth aspect of the present invention provides a deposition method as recited in any one of the first, the third, and the eighth aspects, wherein the catalyst is in a form of particles.

A tenth aspect of the present invention provides a deposition method as recited in any one of the first through the ninth aspects, wherein the catalyst includes a carrier in a form of particles having an average particle diameter of 0.05 mm through 2.0 mm, and a catalyst component in a form of particles, the catalyst component being carried on the carrier and having an average particle diameter of 1 nm through 10 nm.

An eleventh aspect of the present invention provides a deposition method as recited in the second or the fourth aspects, wherein the metal organic compound is trialkyl gallium, and wherein the catalyst includes a ceramic oxide carrier in the form of particles, and particles of at least one metal of platinum (Pt), ruthenium (Ru) and iridium (Ir), the particles of the at least one metal being carried on the carrier.

A twelfth aspect of the present invention provides a deposition method as recited in the eleventh aspect, wherein the carrier is an aluminum oxide carrier, and wherein the particles are ruthenium (Ru) particles.

A thirteenth aspect of the present invention provides a deposition method as recited in any one of the first through the twelfth aspects, wherein the nitrogen supplying gas includes hydrazine.

A fourteenth aspect of the present invention provides a deposition method as recited in any one of the first, and the third through the thirteenth aspects, wherein the catalyst reaction apparatus is arranged in a reaction chamber evacuatable to a reduced pressure.

A fifteenth aspect of the present invention provides a deposition method as recited in any one of the first through the fourteenth aspects, wherein the reactive gas is reacted with the compound gas in a vicinity of a spray outlet of the catalyst reaction apparatus.

A sixteenth aspect of the present invention provides a deposition method as recited in any one of the first through the fifteenth aspects, wherein the reactive gas heated by heat of reaction is generated by contacting the nitrogen supplying gas with the catalyst in the catalyst reaction apparatus.

A seventeenth aspect of the present invention provides a deposition method as recited in any one of the first through the sixteenth aspects, wherein the substrate is selected from a metal, a metal nitride, a glass, a ceramic material, a semiconductor, and a plastic.

An eighteenth aspect of the present invention provides a deposition method as recited in any one of the first through the seventeenth aspects, wherein a temperature of the substrate is in a range of room temperature through 1500° C.

A nineteenth aspect of the present invention provides a deposition method of depositing a nitride film, including: a step of generating a reactive gas by introducing one or more nitrogen supplying gas selected from hydrazine and nitrogen oxides into a catalyst reaction apparatus and by contacting the nitrogen supplying gas with catalyst; a step of enabling the generated reactive gas to be spouted out from the catalyst reaction apparatus and reacted with a compound gas; and a step of depositing a nitride generated through reaction of the reactive gas and the compound gas on a substrate.

A twentieth aspect of the present invention provides a deposition method as recited in the nineteenth aspect, wherein the step of generating the reactive gas includes a step of introducing a reaction control gas that controls reaction of the nitrogen supplying gas with the catalyst into the catalyst reaction apparatus.

A twenty-first aspect of the present invention provides a deposition apparatus of a nitride film, including: a substrate supporting part that supports a substrate; a compound gas supply part that supplies a compound gas; and a catalyst reaction apparatus that accommodates a catalyst capable of generating a reactive gas by being in contact with one or more nitrogen supplying gas selected from hydrazine and nitrogen oxides, thereby enabling the reactive gas to spout out toward the substrate, wherein the compound gas and the reactive gas are reacted with each other in order to deposit a nitride film on the substrate.

A twenty-second aspect of the present invention provides a deposition apparatus as recited in the twenty-first aspect, further comprising a reaction chamber evacuatable to a reduced pressure, wherein the substrate support part and the catalyst reaction apparatus are arranged in the reaction chamber.

A twenty-third aspect of the present invention provides a deposition apparatus as recited in the twenty-first aspect, further comprising a reaction chamber evacuatable to a reduced pressure, wherein the substrate supporting part is arranged in the reaction chamber and the catalyst reaction apparatus is arranged outside the reaction chamber.

### Effects of the Invention

According to an embodiment of the present invention, a nitride film is efficiently formed on various substrates at a low cost, without requiring a large amount of electrical energy.

In addition, because a large amount of ammonia, which is toxic, is not required, differently from the conventional method, an environmental burden can be greatly reduced.

### BRIEF DESCRIPTION OF THE DRAWING

FIG. 1 is a schematic view illustrating a deposition apparatus according to a first embodiment of the present invention;

FIG. 2 is an enlarged schematic cross-sectional view of a catalyst reaction apparatus arranged in the deposition apparatus of FIG. 1;

FIG. 3 is an enlarged schematic cross-sectional view of another catalyst reaction apparatus arranged in the deposition apparatus of FIG. 1;

FIG. 4 is a schematic view illustrating a deposition apparatus according to a second embodiment of the present invention;

FIG. 5 an enlarged schematic cross-sectional view of a catalyst reaction apparatus arranged in the deposition apparatus of FIG. 4;

FIG. 6 is an enlarged schematic cross-sectional view of another catalyst reaction apparatus arranged in the deposition apparatus of FIG. 4;

FIG. 7 is an enlarged schematic cross-sectional view of yet another catalyst reaction apparatus arranged in the deposition apparatus of FIG. 4;

FIG. 8 is a flowchart illustrating a deposition method according to an embodiment of the present invention;

FIG. 9 is a schematic view illustrating a deposition apparatus according to another embodiment of the present invention;

FIG. 10 illustrates an X-ray diffraction (XRD) pattern of a gallium nitride (GaN) film obtained by an example of the deposition method; and

FIG. 11 illustrates a photoluminescence spectrum of a gallium nitride (GaN) film obtained by an example of the deposition method.

### DESCRIPTION OF THE REFERENCE NUMERALS

1, 101, 201 Deposition Apparatus
2, 102, 202 Reaction Chamber
3, 103, 203 Nitrogen Supplying Gas Inlet
4, 104, 204 Spray Nozzle
5, 5′, 105, 205 Catalyst Reaction Apparatus
6, 106, 206 Compound Gas Introducing Nozzle
7, 107, 207 Substrate
8, 108, 208 Substrate Holder
11, 111, 211 Nitrogen Supplying Gas Supply Part
12, 112, 212 Metal Organic Compound Gas Supply Part
13, 113, 213 Evacuation Pipe
14, 114, 214 Turbo Molecular Pump
15, 115, 215 Rotary Pump
21, 31, 221 Catalyst Container Jacket
22, 222 Catalyst Reaction Container
23, 223 Metal Mesh
24, 224 Metal Oxide Gas
25, 25a, 25b, 225 Catalyst
26, 126, 226 Shutter
32 Separator
33 First Catalyst reaction apparatus
34 Second Catalyst reaction apparatus
35 Communication Hole

### BEST MODE OF CARRYING OUT THE INVENTION

Non-limiting, exemplary embodiments of the present invention will now be described with reference to the accompanying drawings. In the drawings, the same or corresponding reference symbols are given to the same or corresponding members or components. It is to be noted that the drawings are illustrative of the invention, and there is no intention to indicate scale or relative proportions among the members or components. Therefore, the specific size should be determined by a person having ordinary skill in the art in view of the following non-limiting embodiments.

### First Embodiment

In a first embodiment of the present invention, one or more nitrogen supplying gas selected from hydrazine and nitrogen oxides is introduced into a catalyst reaction apparatus having a reaction gas spray nozzle arranged within a reaction chamber evacuatable to reduced pressures, and made to come in contact with a catalyst in the form of microparticles. High-energy reactive gas obtained through the contact with the catalyst is sprayed from the catalyst reaction apparatus and reacted with a metal organic compound gas (vapor), in order to deposit a metal nitride film on a substrate.

In other words, by making one or more nitrogen supplying gas selected from hydrazine and nitrogen oxides contact the catalyst in the form of microparticles within the catalyst reaction apparatus to cause the reaction, the reactive gas heated to a high temperature of 700° C. through 800° C. by the heat of reaction is generated. This reactive gas is sprayed from the spray nozzle into the mixture of and reaction with the metal organic compound gas, which is a source material of the metal nitride film, thereby forming the metal nitride film on the substrate surface. Incidentally, the nitrogen supplying gas preferably includes hydrazine.

The catalyst accommodated within the catalyst reaction apparatus may be a carrier in the form of microparticles having an average particle diameter of 0.05 mm through 2.0 mm, the carrier carrying a catalyst component in the form of microparticles having an average particle diameter of 1 nm through 10 nm. In this case, the catalyst component may be metal such as platinum (Pt), ruthenium (Ru), iridium (Ir) , copper (Cu) or the like. In addition, metal powders or microparticles of Pt, Ru, Ir, Cu or the like having an average particle diameter of about 0.1 mm through about 0.5 mm may be used.

As the carrier, microparticles of metal oxides such as aluminum oxide, zirconium oxide and zinc oxide, that is, microparticles of ceramic oxides or zeolites, may be used. An especially preferable carrier may be formed by subjecting porous γ-alumina to a thermal process at 500° C. through 1200° C. to transform the porous γ-alumina into an α-alumina crystal phase while maintaining the surface structure thereof is cited.

A preferably usable catalyst may be the above aluminum oxide carrier that carries nanoparticles of ruthenium or iridium of about 1 wt. % through about 30 wt. % (for example, 10 wt. % Ru/α-Al₂O₃ catalyst).

Next, preferable embodiments of the present invention are described with reference to the drawings, but the following examples do not limit the present invention.

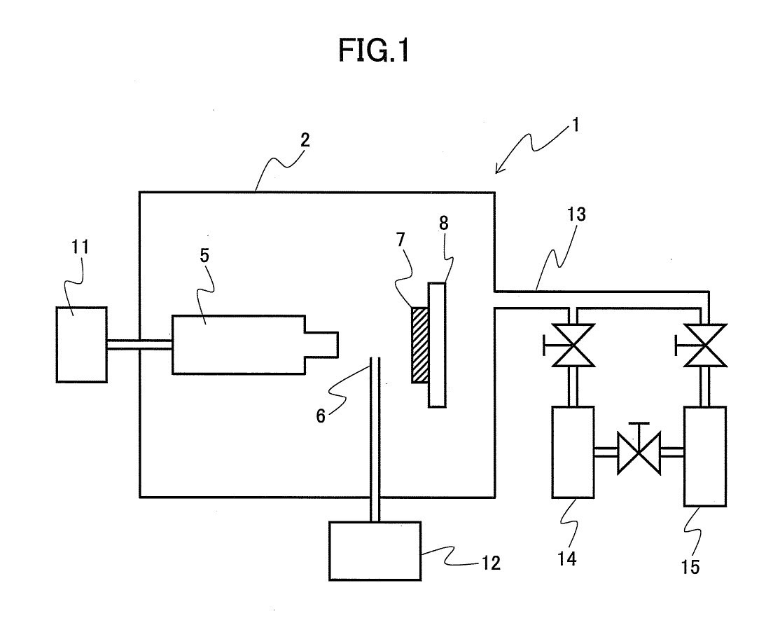

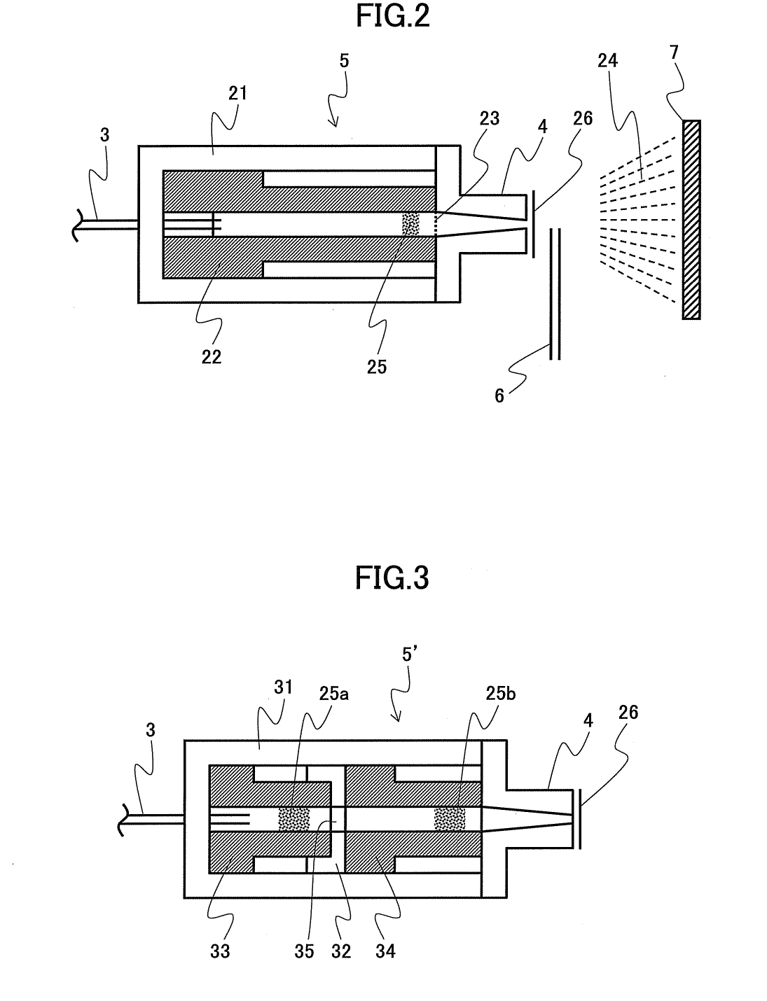

FIG. 1 is a schematic view illustrating a deposition apparatus for forming a nitride film on various substrates, according to a first embodiment of the present invention, and FIG. 2 is an enlarged schematic view illustrating a catalyst reaction apparatus arranged within the deposition apparatus. FIG. 3 is an enlarged cross-sectional view illustrating another example of the catalyst reaction apparatus arranged within the deposition apparatus.

Referring to FIGS. 1 and 2, a reaction apparatus 1 includes a reaction chamber 2 evacuatable to reduced pressures. A catalyst reaction apparatus 5 having a nitrogen supplying gas inlet 3 connected to a nitrogen supplying gas supply part 11 and a reaction gas spray nozzle 4, a metal organic compound gas introducing nozzle 6 connected to a metal organic compound gas supply part 12 that supplies a source material of the nitride film, and a substrate holder 8 that supports a substrate 7 are accommodated within the reaction chamber 2. The reaction chamber 2 is connected to a turbo molecular pump 14 and a rotary pump 15, via an evacuation pipe 13.

Referring to FIG. 2, the catalyst reaction apparatus 5 includes a cylindrical catalyst container jacket 21 made of a metal such as stainless steel, for example. The catalyst container jacket 21 accommodates a catalyst reaction container 22 that is made of a material such as ceramic materials and metals, and the catalyst container jacket 21 is sealed by a spray nozzle 4. A catalyst 25 formed by the carrier in the form of microparticles carrying the catalyst component in the form of ultra-microparticles is arranged within the catalyst reaction container 22. One end portion of the catalyst reaction container 22 is connected to the nitrogen supplying gas supply part 11 via the nitrogen supplying gas inlet 3, and a metal mesh 23 is arranged in order to hold the catalyst 25 in the other end portion.

When one or more nitrogen supplying gas selected from hydrazine and nitrogen oxides is introduced into the catalyst reaction apparatus 5 from the nitrogen supplying gas inlet 3 connected to the nitrogen supplying gas supply part 11, a decomposition reaction of the nitrogen supplying gas occurs due to the catalyst 25 in the form of microparticles. The reaction generates a large amount of heat, and thus a reactive gas heated by the heat of reaction is vigorously spouted out from the reaction gas spray nozzle 4 toward the substrate held by the substrate holder 8. The spouted reactive gas reacts with the metal organic compound gas supplied from the organic metal compound gas introducing nozzle 6 connected to the metal organic compound gas supply part 12, so that a metal nitride gas 24 is generated, and thus the metal nitride film is deposited on the surface of the substrate 7.

A shutter 26 configured to open and close is provided at a distal end of the reaction gas spray nozzle 4 of the catalyst reaction apparatus 5, and blocks a side product gas (premature precursor) from reaching the substrate 7, while the shutter 26 may be omitted. When the shutter 26 is provided, it becomes possible to form a metal nitride film having more uniform properties on the substrate 7. In other words, although a substantial supply ratio of nitrogen and metal is not likely to be a desired value because a temperature of the catalyst 25 is low and thus a decomposition rate of the nitrogen supplying gas is low immediately after the nitrogen supplying gas is introduced into the catalyst reaction apparatus 5, the desired supply ratio can be realized even at an initial stage of the deposition by waiting until the temperature of the catalyst 25 becomes and is stabilized at a predetermined temperature of about 700° C. through 800° C. while keeping the shutter 26 closed, and then the shutter 26 is opened. As a result, a metal nitride film having more uniform properties can be formed.

In addition, as shown in FIG. 3, a catalyst reaction apparatus 5′ may be divided into two compartments by a separator 32 having a communication hole 35 in the center thereof, and a first catalyst reaction container 33 may be arranged in one compartment and a second catalyst reaction container 34 may be arranged. With this, a two-stage catalyst reaction may occur in the catalyst reaction apparatus 5′. For example, when hydrazine is used as the nitrogen supplying gas, a hydrazine decomposing catalyst 25a that decomposes hydrazine into ammonia components may be filled in the first catalyst reaction container 33 and an ammonia decomposing catalyst 25b that decomposes the ammonia components into radicals may be filled in the second catalyst reaction container 34.

As such a hydrazine decomposing catalyst 25a filled in the first catalyst reaction container 33, a carrier in the form of microparticles of, for example, alumina, silica, zeolite or the like carrying iridium ultra-microparticles of about 5 wt. % through about 30 wt. % may be used. In addition, the ammonia decomposing catalyst 25b filled in the second catalyst reaction container 34, the same carrier carrying ruthenium ultra-microparticles of about 2 wt. % through about 10 wt. % may be used.

Such a two-stage decomposition reaction may proceed as follows:

2N₂H₄ - - - >2NH₃+H*₂ (1)

NH₃ - - - >NH*+H*₂, NH*₂+H (2)

Incidentally, the catalyst of the same kind may be filled in the catalyst reaction containers 33, 34. In addition, the catalyst reaction apparatus 5′ may be divided into three or more compartments and the catalyst reaction may be made to occur in three or more stages.

As stated above, in this embodiment of the present invention, one or more nitrogen supplying gases selected from hydrazine and nitrogen oxides are introduced into the catalyst reaction apparatus 5 and high energy reactive gas obtained by making contact with the catalyst in the form of microparticles is spout out from the catalyst reaction apparatus to react with the organic metal compound gas, which makes it possible to efficiently form a metal nitride film on various substrates at a low cost, without requiring a large amount of electrical energy. Such a chemical reaction accompanying the large amount of heat generation is realized for the first time by selecting an appropriate gas as the nitrogen supplying source and using the catalyst in the form of microparticles.

In the first embodiment of the present invention, it becomes possible to form a film and an epitaxial film that have a high quality on a substrate even at a low temperature of 600° C. or lower, which cannot be realized in conventional thermal CVD methods, because it is unnecessary to heat the substrate to a high temperature. Hence, it becomes possible to deposit semiconductor materials and various electronic materials using substrates which were difficult to use in the case of the conventional techniques. In addition, because it is unnecessary to use a large amount of ammonia, which is toxic, while use of a large amount of ammonia is inevitable in the conventional methods, an environmental burden can be significantly reduced.

### Second Embodiment

Next, a second embodiment of the present invention is explained. In this embodiment, one or more nitrogen supplying gases selected from hydrazine and nitrogen oxides, and a reaction control gas that controls the catalyst reaction are separately supplied into the catalyst reaction apparatus to make contact with the catalyst in the microparticle form, in order to obtain a reactive gas, which is spouted out from the catalyst reaction apparatus to be mixed with the metal organic compound gas, which is a source gas of the thin film, in order to form a metal nitride film on the substrate surface.

In other words, the one or more nitrogen supplying gases selected from hydrazine and nitrogen oxides and a reaction control gas that controls the catalyst reaction are made to contact with the catalyst in the microparticle form in the catalyst reaction apparatus in order to generate the reactive gas heated at about 300° C. through about 800° C., and this reactive gas is spouted out from the spray nozzle to be mixed with the metal organic compound gas, thereby forming the metal nitride film on the substrate surface. The nitrogen supplying gas preferably includes hydrazine.

Incidentally, because the catalyst carrier and the catalyst that are accommodated in the catalyst reaction apparatus are the same as the catalyst carrier and the catalyst in the first embodiment, redundant description is omitted.

Next, this embodiment is explained with reference to the drawings, but the present invention is not limited to the examples described hereinafter.

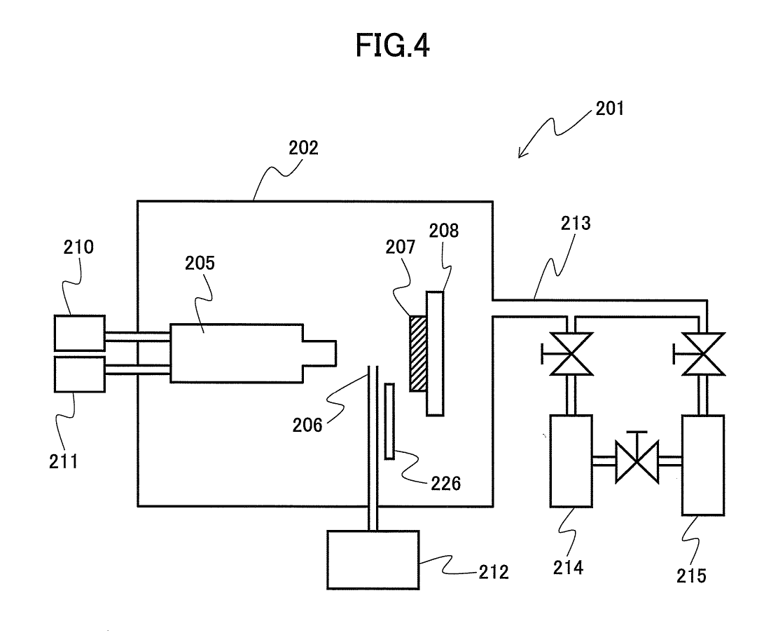

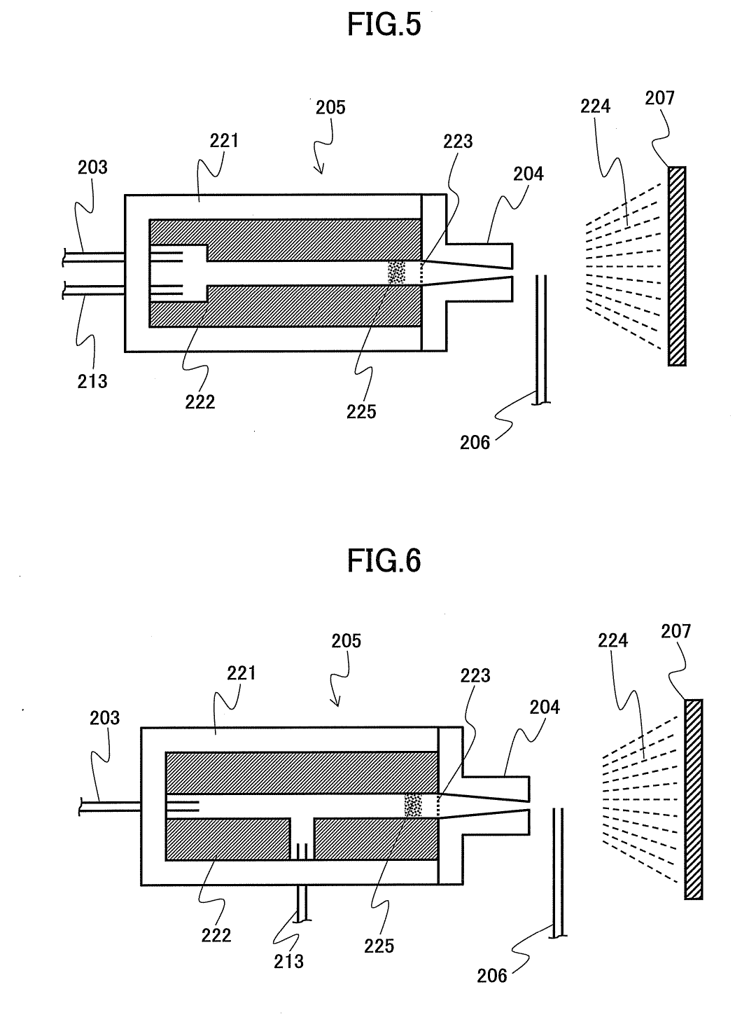

FIG. 4 is a schematic view illustrating a reaction apparatus in which a nitride film is formed on various substrates, and FIG. 5 is an enlarged schematic view of a catalyst reaction apparatus arranged within the reaction apparatus.

A reaction apparatus 201 includes a reaction chamber 202 evacuatable to reduced pressures. Within the reaction chamber 202, a compound gas introducing nozzle 206 connected to a metal organic compound gas supply part 212 in order to supply a metal organic compound to be used as a source material of a metal nitride in this embodiment, and a substrate holder 208 that supports a substrate 207 are accommodated. The reaction chamber 202 is connected to a turbo molecular pump 214 and a rotary pump 215, via an exhaust pipe 213.

A nitrogen supplying gas supply part 210 that supplies a nitrogen supplying gas for nitriding the metal organic compound to form a nitride film, and a reaction control gas supplying part 211 that supplies a reaction control gas for diluting the nitrogen supplying gas to control the catalyst reaction are connected to the reaction chamber 202 evacuatable to reduced pressures. Specifically, the nitrogen supplying gas supply part 210 is connected to the catalyst reaction apparatus 205 arranged in the reaction chamber 22, via a nitrogen supplying gas inlet 203 (FIG. 5). As the reaction control gas, a nitrogen containing gas such as ammonia, nitrogen, or the like can be used. In addition, the reaction control gas may be an inert gas such as helium (He), argon (Ar), or the like, or hydrogen (H₂) gas.

The catalyst reaction apparatus 205 is composed of a cylindrical catalyst container jacket 221 that is made of a metal such as stainless steel, for example, a catalyst reaction container 222 that is made of a material such as ceramics and metals, and accommodated in the catalyst container jacket 221, and a spray nozzle 204 attached to the catalyst container jacket 221.

A catalyst 225 formed by a carrier in the form of microparticles carrying the catalyst component in the form of ultra-microparticles is arranged within the catalyst reaction container 222. One end portion of the catalyst reaction container 222 is connected to the nitrogen supplying gas supply part 210 via the nitrogen supplying gas inlet 203. In the other end portion, a metal mesh 223 to hold the catalyst 225 is arranged in order that the catalyst 225 is not blown out from the catalyst reaction apparatus 205 through the spray nozzle 204.

The nitrogen supplying gas is supplied to the catalyst reaction apparatus 205 (the catalyst container jacket 221) from the nitrogen supplying gas inlet 203 connected to the nitrogen supplying gas supply part 210, and the reaction control gas is supplied to the catalyst reaction apparatus 205 from the reaction control gas inlet 213 connected to the reaction control gas supply part 211. For example, by introducing hydrazine as the nitrogen supplying gas and ammonia as the reaction control gas into the catalyst container jacket 221, a concentration of the hydrazine in the catalyst container jacket 221 can be adjusted by the ammonia. While decomposition of the hydrazine due to the catalyst in the form of microparticles generates a large amount of heat, by controlling the concentration of the hydrazine with the ammonia, a temperature of the catalyst container jacket 221 can be adjusted. In addition, part of the ammonia is decomposed by the catalyst 225 in the catalyst container jacket 221, thereby serving as a reactive gas reactive with a metal compound gas.

Incidentally, by supplying the hydrazine as the nitrogen supplying gas and nitrogen (N2) as the reaction control gas into the catalyst container jacket 221, the concentration of the hydrazine in the catalyst container jacket 221 can be controlled by N2 in the same manner.

In this manner, the reactive gas whose temperature is controlled is vigorously spouted out from the spray nozzle 204 toward the substrate 207 held by the substrate holder 208. This reactive gas reacts with the metal organic compound gas supplied from the compound gas introducing nozzle 206 in the vicinity of the substrate 207 to become metal nitride 224, and a metal nitride film is deposited on the surface of the substrate 207.

Incidentally, an openable/closable shutter 226 (illustrated in an open state) may be provided between the catalyst reaction apparatus 205 and the substrate 207 in the same manner as the first embodiment, and a side product gas (a gas inappropriate for film deposition, which is spouted out from the catalyst reaction apparatus 205 before reaching a state where a deposition process can stably proceeds) may be blocked. When adopting such a configuration, a metal nitride film having more uniform properties can be formed on the substrate 207.

As stated above, in. the second embodiment, because the nitrogen supplying gas to be a nitrogen source of the metal nitride film is introduced into the catalyst reaction apparatus 205, and the reactive gas obtained by contacting the nitrogen supplying gas with the catalyst in the form of microparticles is spouted out from the catalyst reaction apparatus 205 to react with the metal organic compound gas, the metal nitride film can be efficiently formed at a low cost on various substrates, without requiring a large amount of electrical energy. Such a chemical reaction accompanying the large amount of heat generation is realized for the first time by selecting an appropriate gas as the nitrogen source and using the catalyst in the form of microparticles.

In the second embodiment of the present invention, it becomes possible to form a nitride film having a high quality on the substrate even at a low temperature of 400° C. or lower, which cannot be realized in conventional thermal CVD methods, because it is unnecessary to heat the substrate to a high temperature. Hence, it becomes possible to deposit semiconductor materials and various electronic materials using substrates which were difficult to use in the case of the conventional techniques.

In addition, in the film deposition apparatus 201 according to this embodiment, because not only the nitrogen supplying gas supply part 201 is connected to the catalyst reaction apparatus 205 via the nitrogen gas supplying inlet 203 (FIG. 5), but also the reaction control gas supplying part 211 is connected to the catalyst reaction apparatus 205 via the reaction control gas inlet 213 (FIG. 5), the ammonia or N2, for example, as the reaction control gas can be introduced into the catalyst reaction apparatus 205 together with the hydrazine as the nitrogen supplying gas. With this, an amount of the reaction gas generated by decomposing the hydrazine with the catalyst 225, namely an amount of gas to be supplied to the substrate 207 can be controlled. As a result, properties of the nitride film deposited on the substrate 207 can be improved. In addition, by controlling a concentration of the hydrazine, an amount of heat through decomposition can be controlled. Because not only a temperature of the catalyst 225 but also a temperature of the reactive gas can be controlled, the properties of the nitride film deposited on the substrate 207 can be improved. In other words, according to the second embodiment of the present invention, a process window can be widened due to use of the reaction control gas, thereby producing a high quality nitride film through optimization of deposition conditions. Incidentally, the nitrogen supplying gas inlet 203 and the reaction control gas inlet 213 are connected to the catalyst reaction apparatus 205 at positions opposing the reactive gas spray nozzle 204 as shown in FIG. 5 in this embodiment. However, one of the nitrogen supplying gas inlet 203 and the reaction control gas inlet 213 may be connected in a position opposing the reactive gas spray nozzle 204, and the other is connected in a position of a side surface of the catalyst reaction apparatus 205, in another embodiment as shown in FIG. 6.

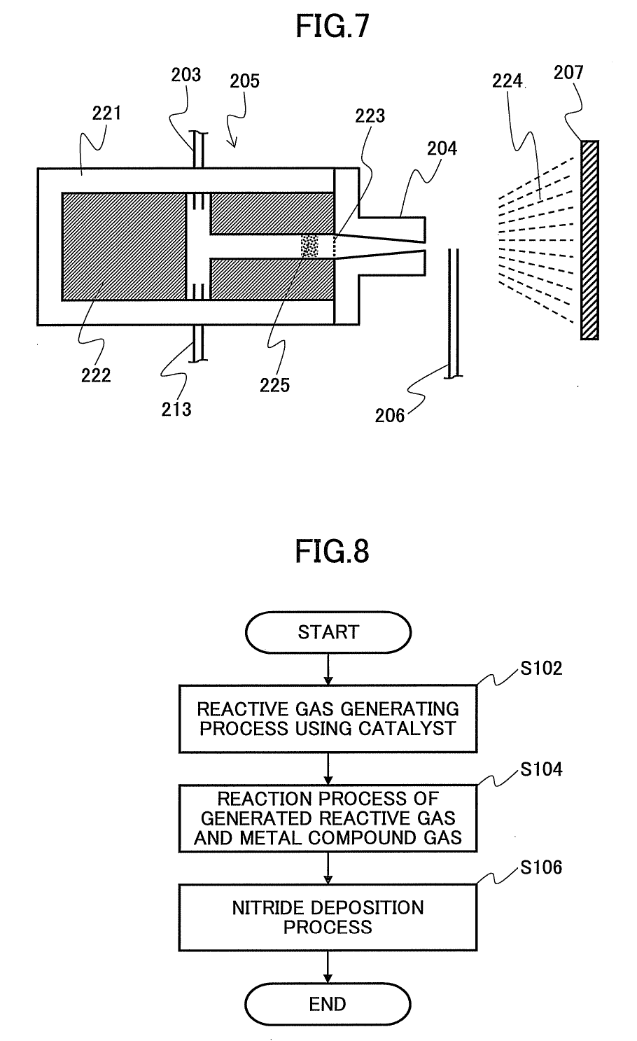

Additionally, the nitrogen supplying gas inlet 203 and the reaction control gas inlet 213 are connected in positions of the side surface of the catalyst reaction apparatus 205, in yet another embodiment as shown in FIG. 7. Even with these configurations, the above effects are obtained.

Next, based on FIG. 8, a deposition process of a metal nitride film according to this embodiment is explained in detail.

First, the nitrogen supplying gas is introduced into the catalyst reaction apparatus 205 from the nitrogen supplying gas supply part 210 via the nitrogen supplying gas inlet 203 (FIG. 5). The nitrogen supplying gas may be one or more nitrogen supplying gas selected from hydrazine and nitrogen oxides, and preferably includes hydrazine. When the nitrogen supplying gas is introduced into the catalyst reaction apparatus 205, at least part of the nitrogen supplying gas is decomposed by the catalyst in the form of microparticles and thus the reactive gas is generated, as shown in Step S102. This decomposition accompanies a large amount of heat and the high temperature reactive gas heated by the reaction heat is vigorously spouted out from the reaction gas spray nozzle 204 toward the substrate 207 held by the substrate holder 208.

Next, as shown in Step S104, when the metal organic compound gas is supplied from the metal organic compound gas supply part 212, the generated reactive gas and the metal organic compound gas are chemically reacted with each other, and the metal nitride gas 224 is generated between the catalyst reaction apparatus 205 and the substrate 207, or in the vicinity of the reaction gas spray nozzle 204 of the catalyst reaction apparatus 205.

Next, as shown in Step S106, the metal nitride gas 224 is adsorbed on the surface of the substrate 207, and the metal nitride film is deposited on the substrate 207. With these procedures, the deposition of the metal nitride film is carried out.

Incidentally, Steps S102 and S104 are not carried out in the above order. For example, introduction of the nitrogen supplying gas into the catalyst reaction apparatus 205 in Step S102 and supplying of the metal organic compound gas in Step S104 may be concurrently carried out. In addition, the supplying of the metal organic compound gas may be carried out prior to the introduction of the nitrogen supplying gas.

Additionally, at Step S102, the reaction control gas may be supplied into the catalyst reaction apparatus 205 in addition to supplying of the nitrogen supplying gas into the catalyst reaction apparatus 205, in Step S102. Moreover, another compound gas may be supplied rather than a metal organic compound gas in Step S104.

### EXAMPLES

Next, the present invention is further explained with reference to Examples, but the present invention is not limited by the following specific examples. In the following example, a gallium nitride film is formed on a silicon substrate using the reaction apparatus shown in FIGS. 1 and 2.

### Example 1

γ-Al₂O₃ carriers having an average particle diameter of 0.3 mm were sintered at 1000° C. under atmosphere for four hours to obtain α-Al₂O₃ carriers 109. These carriers were impregnated with 0.943 g of ruthenium chloride and then sintered at 450° C. under air for four hours, thereby obtaining 3 wt. % Ru/α-Al₂O₃ catalyst.

After 5 g of the 3 wt. % Ru/γ-Al₂O₃catalyst was loaded to the catalyst reaction container 22 and the metal mesh 23 was arranged, the catalyst reaction apparatus 5 is configured by attaching the spray nozzle 4 and arranged in the reaction chamber 2 evacuatable to reduced pressures.

The hydrazine was introduced into the catalyst reaction apparatus 5 from the nitrogen supplying gas supply part 11 by opening for a short period of time and closing a valve (not shown) (valve opening period of 20 ms), and decomposed at the surface of the catalyst, thereby generating hydrazine decomposition gas at a temperature of 700° C. in the catalyst reaction container 22. Then, the hydrazine decomposition gas was spouted out from the spray nozzle 4 while the shutter 26 arranged around the distal end of the nozzle. (In this situation, the hydrazine decomposition gas is spouted from side ends of the shutter 26 in a direction parallel with the substrate 207, and does not reach the substrate 207.)

On the other hand, trimethyl gallium was introduced into the reaction chamber 2 at 1×10−3 Torr (0.133 Pa) from the metal organic compound gas supply part 12 via the compound gas introducing nozzle 6, and made to come into contact with the high temperature hydrazine decomposition gas to form a GaN precursor.

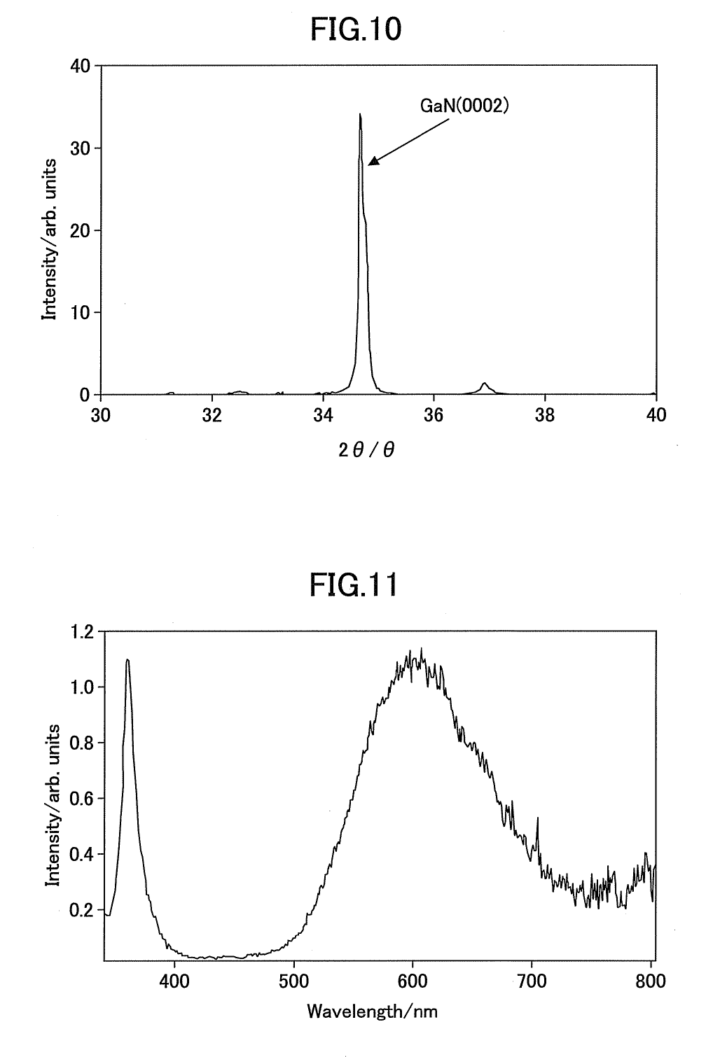

Next, the GaN precursor was supplied to a surface of a single crystal silicon substrate (size: 5 mm×20 mm) whose surface temperature of 600° C. arranged in the reaction chamber 2, by opening the shutter 26 of the catalyst reaction apparatus 5, thereby depositing a GaN film. In this example, a GaN film having a thickness of about 1 μm was obtained for a deposition time of 20 seconds. An X-ray diffraction (XRD) pattern measured with respect to the obtained GaN film is shown in FIG. 10, and a photoluminescence (PL) spectrum is shown in FIG. 11. In the XRD pattern, diffraction from a (0002) surface is significantly observed, which indicates that a single crystal GaN film is obtained. In addition, in the PL spectrum, a band edge emission having a narrow full-width at half maximum is observed, which indicates an optically excellent GaN film is obtained. With these results, advantages of the film deposition apparatus and method according to an embodiment of the present invention can be understood. Incidentally, the similar results have been obtained when a sapphire substrate is used instead of the silicon substrate.

In the embodiments of the present invention, it becomes possible to efficiently form a nitride film having a high quality on the substrate at a low cost, without requiring a large amount of electrical energy, by introducing one or more nitrogen supplying gases selected from hydrazine and nitrogen oxides into the catalyst reaction apparatus, allowing the high energy reactive gas obtained by making contact with the catalyst in the form of microparticles to spout out from the catalyst reaction apparatus, and making the reactive gas to react with the compound gas. In addition, because it is unnecessary to use a large amount of ammonia, which is toxic, while use of a large amount of ammonia is inevitable in the conventional methods, environmental load can be significantly reduced.

While the present invention has been explained with reference to a few embodiments, the present invention is not limited to those embodiments, but may be variously modified and altered in view of the scope of the accompanying claims.

For example, a nitride to be deposited on the surface of the substrate, a metal compound gas to be a source material of the nitride, a substrate used, and a shape of a catalyst are variously modified in the following manner in the first and the second embodiments.

As the nitride to be deposited on the surface of the substrate, there may be recited metal nitrides such as aluminum nitride, indinum nitride, gallium indium nitride (GaInN), gallium aluminum nitride (GaAlN), gallium indium aluminum nitride (GaInAlN) and a semi-metal nitride, without being limited to the gallium nitride described above. The semi-metal nitride includes a semiconductor nitride, an example of which is silicon nitride.

When depositing a metal nitride film, a metal compound gas as a source is not specifically limited. For example, any metal organic compound gas that is used to form a metal nitride by conventional CVD methods may be used. As such an metal organic compound, there may be recited alkyl compounds, alkenyl compounds, phenyl or alkyl phenyl compounds, alkoxide compounds, di-pivaloyl methane compounds, halides, acetylacetonate compounds, EDTA compounds or the like of various metals.

As a preferable metal organic compound there may be recited alkyl compounds and alkoxide compounds of various metals. Specifically, trimethyl gallium, triethyl gallium, trimethyl aluminum, triethyl aluminum, trimethyl indium, triethyl indium, triethoxy gallium, triethoxy aluminum, triethoxy indium, or the like may be cited.

When depositing a gallium nitride film on a surface of a substrate, preferably, trialkyl gallium such as trimethyl gallium and triethyl gallium is used as a source material and porous alumina in the form of microparticles carrying ruthenium ultra-micropartcles is used as catalyst.

In addition, a metal compound gas to be a source material of a metal nitride is not limited to the metal organic compound gases, but may be an inorganic metal compound. The inorganic metal compound is, for example but not limited to a halide gas except for the metal organic compounds, and specifically, chloride gases such as gallium chloride gases (GaCl, GaCl2, GaCl3). In addition, when the inorganic metal compound gas is used, a gas cylinder filled with the inorganic metal gas is provided in the deposition apparatus 1 (201, 101), in the place of the metal organic compound supply part 212, and the inorganic metal compound gas may be introduced via the compound gas introducing nozzle 6 (206, 106).

When the silicon nitride film is formed on the substrate surface, silicon hydrides, silicon halides, and organic silicon compounds, for example, can be used as the silicon source material. As an example of the silicon hydrides, there maybe silane and disilane. As an example of the silicon halides, there may be silicon chlorides such as dichlorosilane, trichlorosilane, and tetrachlorosilane. As an example of the organic silicon compounds, there may be tetraethoxysilane, tetramethoxysilane, or hexamethyldisilazane.

A substrate to be used may be selected from metal, metal nitride, glass, ceramic material, semiconductor, and plastic.

As a preferable substrate, a compound single crystal substrate typified by sapphire or the like, a single crystal substrate typified by silicon or the like, an amorphous substrate typified by glass, an engineering plastic substrate such as polyimide may be recited.

In addition, the carrier may have a bulk shape including a honeycomb shape with penetrating holes, a porous form such as a sponge shape, or the like. Moreover, the shape or form of the catalyst material, such as Pt, Ru, Ir and Cu, is not limited to the microparticle form, but may be a film form, for example. A surface area of the catalyst material is preferably large in order to certainly obtain the effects of this embodiment. Therefore, when the film of the catalyst material is formed on the above carriers, for example, the effects similar to those obtainable in the case of the microparticle form can also be obtained because the surface area of the catalyst material can be enlarged.

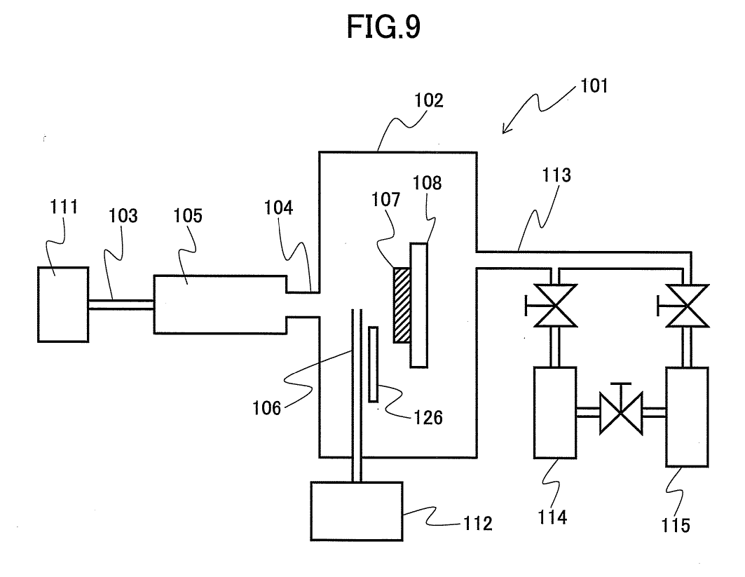

In addition, while the catalyst reaction apparatus 205 is arranged within the reaction chamber 202 in the film deposition apparatus 1 of the first embodiment and the film deposition apparatus 201 of the second embodiment, the catalyst reaction apparatus 205 is arranged outside and connected to the reaction chamber 202. Such an arrangement is shown in FIG. 9. As shown, in a reaction apparatus 101, the catalyst reaction apparatus 105 having a reaction gas spray nozzle 104 and a nitrogen supplying gas inlet 103 connected to a nitrogen supplying gas supply part 111 is arranged outside a reaction chamber 102, and connected to the reaction chamber 102 evacuatable to reduced pressures via the reaction gas spray nozzle 104. In addition, a compound gas introducing nozzle 106 connected to the metal organic compound gas supply part 112 that supplies the metal organic compounds (including silicon organic compounds) as a source material of the silicon nitride film, and a substrate holder 108 that supports the substrate 107 are arranged in the reaction chamber 102 evacuatable to reduced pressures. Moreover, the reaction chamber 102 is connected to the rotary pump 115 and the turbo molecular pump 114 via the evacuation pipe 113. Incidentally, even in the reaction apparatus 101 shown in FIG. 9, the shutter 126 that can be opened and closed (illustrated in an open state) may be provided between the catalyst reaction apparatus 105 and the substrate 107, in order to block the side product gas in an initial stage of reaction. When such a configuration is adopted, a silicon nitride film having more uniform properties can be formed on the substrate 107.

Incidentally, while the film deposition apparatus 1 of the first embodiment was used in the above examples, it has been found that similar results are obtained even when the film deposition apparatus 201 shown in FIG. 5 and the film deposition apparatus 101 shown in FIG. 9. In addition, it has been confirmed that a high quality GaN film is obtained in a substrate temperature range of room temperature through 1500° C. However, a substrate temperature is more preferably in a range of about 500° C. through about 1200° C.

In addition, while the reaction control gas and the nitrogen supplying gas are separately introduced into the catalyst reaction apparatus 205 in the film deposition apparatus 201 of the second embodiment, the nitrogen supplying gas supply part 11 may be configured so that a mixture gas of the reaction control gas and the nitrogen supplying gas can be supplied and the gas mixture is introduced into the catalyst reaction apparatus 5, in the film deposition apparatus 1 of the first embodiment.

Moreover, while only one metal organic compound gas supply part 12 (212, 112) is shown in FIG. 1 (4, 9), the film deposition apparatus 1 (201, 101) may have plural metal organic compound gas supply parts 12 (212, 112) and corresponding compound gas introducing nozzles 6 (206, 106). In this manner, deposition of a ternary mixed crystal material such as GaInN and GaAlN, and a quaternary mixed crystal material such as GaInAlN becomes possible, and growth of hetero-epitaxial films including binary compounds such as GaN and AlN, the above mixed crystal, or the like becomes possible.

In addition, the substrate holder 208 of the film deposition apparatuses 1, 201, 101 may horizontally support the substrate 207, rather than vertically. Moreover, the substrate holder 208 may be provided with a temperature controller that controls a temperature of the substrate 207, so that a temperature of the substrate 207 may be controlled in a range of room temperature through 1500° C. The temperature controller may be configured not only in order to increase a temperature of the substrate 207 but also in order to cool the substrate 207 so that a temperature of the substrate 207 is not excessively increased.

This application claims the benefit of a Japanese Patent Application No.2007-189475 filed on Jul. 20, 2007, in the Japanese Patent Office, the disclosure of which is hereby incorporated by reference.

1. A deposition method of depositing a nitride film, comprising:
introducing one or more nitrogen supplying gases selected from hydrazine and nitrogen oxides into a catalyst reaction apparatus;
enabling a reactive gas generated by contacting the nitrogen supplying gas with catalyst to be spouted out from the catalyst reaction apparatus; and
reacting the reactive gas with a compound gas, thereby depositing a nitride film on a substrate.

2. The deposition method as recited in claim 1, wherein the catalyst reaction apparatus is arranged in a reaction chamber evacuatable to a reduced pressure;
wherein the catalyst is in a form of particles; and
wherein the compound gas is a metal organic compound gas.

3. The deposition method as recited in claim 1, wherein the compound gas is a gas of a metal compound.

4. The deposition method as recited in claim 3, wherein the metal compound is a metal organic compound.

5. The deposition method as recited in claim 4, wherein the metal organic compound is a metal organic compound of at least one kind of metal selected from gallium, aluminum, and indium.

6. The deposition method as recited in claim 1, wherein the compound gas is a gallium-containing gas.

7. The deposition method as recited in claim 1, wherein the compound gas is a gas of a silicon compound.

8. The deposition method as recited in claim 7, wherein the silicon compound is one of an organic silicon compound, a silicon hydride, and a silicon halide.

9. The deposition method as recited claim 1, wherein the catalyst is in a form of particles.

10. The deposition method as recited in claim 1, wherein the catalyst includes a carrier in a form of particles having an average particle diameter of 0.05 mm through 2.0 mm, and a catalyst component in a form of particles, the catalyst component being carried on the carrier and having an average particle diameter of 1 nm through 10 nm.

11. The deposition method as recited claim 2, wherein the metal organic compound is trialkyl gallium, and
wherein the catalyst includes a ceramic oxide carrier in the form of particles, and particles of at least one metal of platinum (Pt), ruthenium (Ru) and iridium (Ir), the particles of the at least one metal being carried on the carrier.

12. The deposition method as recited in claim 11, wherein the carrier is an aluminum oxide carrier, and
wherein the particles are ruthenium (Ru) particles.

13. The deposition method as recited in claim 1, wherein the nitrogen supplying gas includes hydrazine.

14. The deposition method as recited in claim 1, wherein the catalyst reaction apparatus is arranged in a reaction chamber evacuatable to a reduced pressure.

15. The deposition method as recited in claim 1, wherein the reactive gas is reacted with the compound gas in a vicinity of a spray outlet of the catalyst reaction apparatus.

16. The deposition method as recited in claim 1, wherein the reactive gas heated by heat of reaction is generated by contacting the nitrogen supplying gas with the catalyst in the catalyst reaction apparatus.

17. The deposition method as recited in claim 1, wherein the substrate is selected from a metal, a metal nitride, a glass, a ceramic material, a semiconductor, and a plastic.

18. The deposition method as recited in claim 1, wherein a temperature of the substrate is in a range of room temperature through 1500° C.

19. A deposition method of depositing a nitride film, comprising:
a step of generating a reactive gas by introducing one or more nitrogen supplying gas selected from hydrazine and nitrogen oxides into a catalyst reaction apparatus and by contacting the nitrogen supplying gas with catalyst;
a step of enabling the generated reactive gas to be spouted out from the catalyst reaction apparatus and reacted with a compound gas; and
a step of depositing a nitride generated through reaction of the reactive gas and the compound gas on a substrate.

20. The deposition method as recited in claim 19, wherein the step of generating the reactive gas includes a step of introducing a reaction control gas that controls reaction of the nitrogen supplying gas with the catalyst into the catalyst reaction apparatus.

21. A deposition apparatus of a nitride film, comprising:
a substrate supporting part that supports a substrate;
a compound gas supply part that supplies a compound gas; and
a catalyst reaction apparatus that accommodates catalyst capable of generating a reactive gas by being contact with one or more nitrogen supplying gas selected from hydrazine and nitrogen oxides, thereby enabling the reactive gas to spout out toward the substrate,
wherein the compound gas and the reactive gas are reacted with each other in order to deposit a nitride film on the substrate.

22. The deposition apparatus as recited in claim 21, further comprising a reaction chamber evacuatable to a reduced pressure, wherein the substrate support part and the catalyst reaction apparatus are arranged in the reaction chamber.

23. The deposition apparatus as recited in claim 21, further comprising a reaction chamber evacuatable to a reduced pressure, wherein the substrate supporting part is arranged in the reaction chamber and the catalyst reaction apparatus is arranged outside the reaction chamber.
